(19) United States
(12) Patent Application Publication
(10) Pub. No.: US 2010/0163299 A1
(43) Pub. Date: Jul. 1, 2010

(54) ELECTRONIC DEVICE AND HIGH FREQUENCY CIRCUIT BOARD THEREOF

(76) Inventors: Hsu-Kuan Hsu, Taoyuan (TW); Ching-Jung Tsai, Taoyuan (TW); Shih-Nien Huang, Taoyuan (TW); Wei-Chih Chang, Taoyuan (TW)

Correspondence Address: BIRCH STEWART KOLASCH & BIRCH, PO BOX 747, FALLS CHURCH, VA, 22040-0747, US

(21) Appl. No.: 12/639,150

(22) Filed: Dec. 16, 2009

(30) Foreign Application Priority Data
Dec. 31, 2008 (TW) 97151736

(51) Int. Cl. H05K 9/00

(52) U.S. Cl. 174/394; 174/350; 361/818

(57) ABSTRACT

An electronic device and a high frequency circuit board thereof are disclosed. The high frequency circuit board includes a first dielectric layer, a first signal line formed on the first dielectric layer, a second dielectric layer overlaying the first dielectric layer and covering the first signal line, and a first EMI shielding layer overlaying the second dielectric layer. The first EMI shielding layer has a gap formed thereon. The gap is formed at a position corresponding to the position of the first signal line.

### CROSS REFERENCE TO RELATED APPLICATIONS

This application claims priority of Taiwan Patent Application No. 097151736, filed on Dec. 31, 2008, the entirety of which is incorporated by reference herein.

### BACKGROUND OF THE INVENTION

1. Field of the Invention

The invention relates to an electronic device and a high frequency circuit board thereof, and more particularly to an electronic device and a high frequency circuit board thereof to transmit a signal having a frequency higher than 100 MHz.

2. Description of the Related Art

FIG. 1 is a schematic view of a conventional circuit board. Referring to FIG. 1, the conventional circuit board 10 comprises a first dielectric layer 12, a second dielectric layer 11, two EMI shielding layers 13 and 14, and a signal line 16. The signal line 16 is disposed on the first dielectric layer 12. The second dielectric layer 11 is disposed on the first dielectric layer 12 and covers the signal line 16. The second dielectric layer 11 is covered by the EMI shielding layer 13. The EMI shielding layer 13 is a metal layer to provide shielding effectiveness and to prevent the signal line 16 from electromagnetic interference caused by other electric elements. The first dielectric layer 12 and the second dielectric layer 11 are overlapped to each other. The shielding layer 14 covers the lower surface of the first dielectric layer 12. Although the shielding layers 13 and 14 provide shielding effectiveness, the first dielectric layer 12 and the second dielectric layer 11 are coated via the metal layer, resulting in decreasing the overall impedance of the circuit board 10. In addition, if the impedance of the conventional circuit board 10 needs to be increased to the impedance required by the high frequency circuit board 20, the heights H2 and H1 of the second dielectric layer 11 and the first dielectric layer 12 have to be increased accordingly, that is, the impedance Z₀ can be increased by increasing the heights of the second dielectric layer 11 and the first dielectric layer 12. Thus, the overall thickness of the high frequency circuit board 10 is substantially increased, hindering thinner and lighter weight trends for an electronic device.

### BRIEF SUMMARY OF THE INVENTION

The invention provides an electronic device and a high frequency circuit board thereof for transmitting a signal having a frequency higher than 100 MHz.

The high frequency circuit board includes a first dielectric layer, a first signal line formed on an upper surface of the first dielectric layer, a second dielectric layer overlaying the upper surface of the first dielectric layer and covering the first signal line, and a first EMI shielding layer overlaying the second dielectric layer. The first EMI shielding layer has a gap formed thereon. The gap is formed at a position corresponding to the position of the first signal line.

In one embodiment of the present disclosure, the second dielectric layer defines a first projection area on which the first signal line is vertically projected, and the first projection area is positioned within the gap. The first EMI shielding layer has a first side and a second side defining the gap therebetween. The first projection area is positioned between the first side and the second side. An interval between the first projection area and the first side is 0.5 to 3 times the width of the first signal line.

In one embodiment of the present disclosure, the high frequency circuit board further comprises a second signal line formed on the first dielectric layer.

The present disclosure also provides an electronic device comprises the above high frequency circuit board.

### BRIEF DESCRIPTION OF DRAWINGS

The invention can be more fully understood by reading the subsequent detailed description and examples with references made to the accompanying drawings, wherein:

FIG. 1 is a schematic view of a conventional circuit board;

FIG. 2 is a schematic cross-sectional view of a high frequency circuit board according to one embodiment of the present invention;

FIG. 3 is a schematic cross-sectional view of a high frequency circuit board according to another embodiment of the present invention;

FIG. 4 is a schematic cross-sectional view of a high frequency circuit board according to another embodiment of the present invention; and

FIG. 5 is a schematic view of an electronic device according to one embodiment of the present invention.

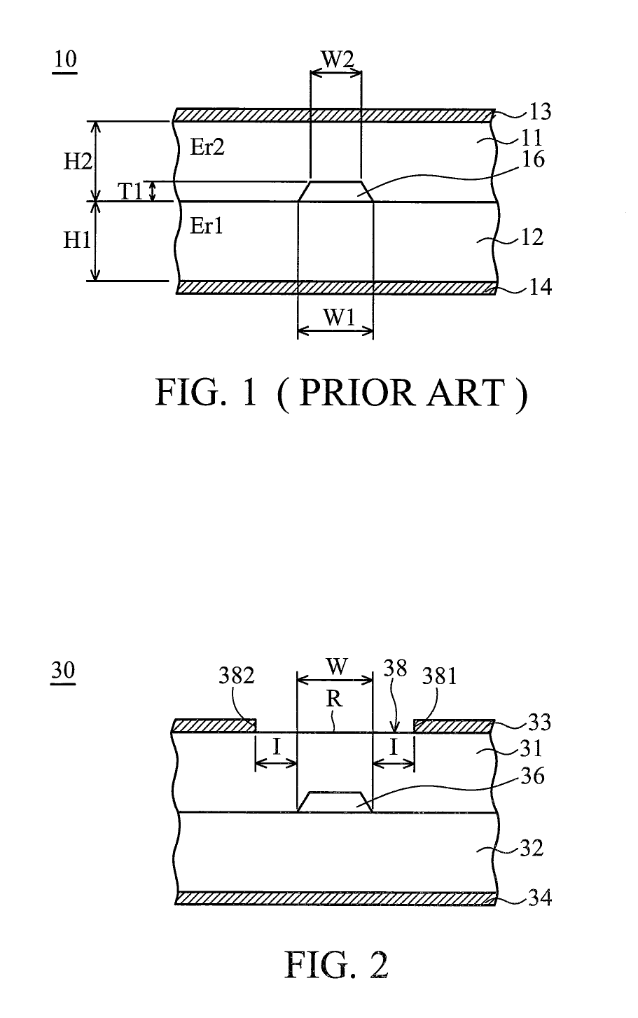

The invention can be more fully understood by reading the subsequent detailed description and examples with references made to the accompanying drawings.

### DETAILED DESCRIPTION OF THE INVENTION

FIG. 2 is a schematic cross-sectional view of a high frequency circuit board according to one embodiment of the present invention. Referring to FIG. 2, the high frequency circuit board 30 comprises a first dielectric layer 32, a second dielectric layer 31, a first signal line 36, a first electromagnetic interference (EMI) shielding layer 33 and a second electromagnetic interference (EMI) shielding layer 34. The first signal line 36 is formed on an upper surface of the first dielectric layer 32. The second dielectric layer 31 overlays the upper surface of the first dielectric layer 32 and covers the first signal line 36. The first EMI shielding layer 33 overlays the second dielectric layer 31 and has a gap 38 formed thereon and at a position corresponding to the position of the first signal line 36. The first dielectric layer 32 and the second dielectric layer 31 are overlapped to each other. The first dielectric layer 32 is made of a dielectric material. The second EMI shielding layer 34 covers a lower surface of the first dielectric layer 32.

As shown in FIG. 2, the second dielectric layer 31 defines a first projection area R on which the first signal line 36 is vertically projected. The first projection area R is positioned within the gap 38. In this embodiment, the first projection area R is positioned at the center of the gap 38. The first EMI shielding layer 33 has a first side 381 and a second side 382 defining the gap 38 therebetween. Two intervals I are respectively between the projection area R and the first and second sides 381, 382. Each interval I is 0.5 to 3 times the width of the first signal line 36. The interval I is in proportion to the impedance of the high frequency circuit board 30. Further, when the interval I is greater, the impedance of the high frequency circuit board 30 becomes greater.

It should be noted that the high frequency circuit board 30 is configured to transmit a high frequency signal having a frequency higher than 100 MHz. The high frequency circuit board 30 may be a hard circuit board or a flexible circuit board.

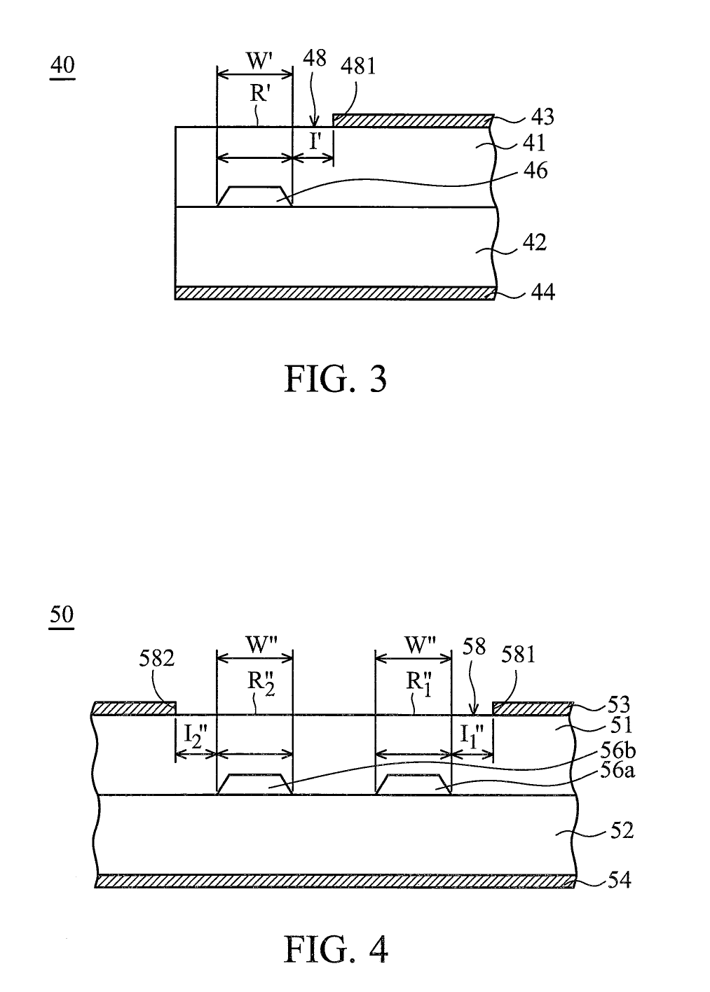

FIG. 3 is a schematic cross-sectional view of a high frequency circuit board according to another embodiment of the present invention. In FIG. 3, the high frequency circuit board 40 comprises a first dielectric layer 42, a second dielectric layer 41, a first signal line 46, a first electromagnetic interference (EMI) shielding layer 43 and a second electromagnetic interference (EMI) shielding layer 44. The first signal line 46 is formed on an upper surface of the first dielectric layer 42. The second dielectric 41 overlays the upper surface of the first dielectric layer 42 and covers the first signal line 46. The first EMI shielding layer 43 overlays the second dielectric layer 41 and has a gap 48 formed thereon and at a position corresponding to the position of the first signal line 46. The first dielectric layer 42 and the second dielectric layer 41 are overlapped to each other. The first dielectric layer 42 is made of a dielectric material. The second EMI shielding layer 44 covers a lower surface of the first dielectric layer 42.

As shown in FIG. 3, the second dielectric layer 41 defines a first projection area R′ on which the first signal line 46 is vertically projected. The first projection area R′ is positioned within the gap 48. In this embodiment, the first signal line 46 is positioned close to the edge of the high frequency circuit board 40, and the first EMI shielding layer 43 only has a first side 481 defining one edge of the gap 48. An interval I′ is between the projection area R′ and the first side 481 and 0.5 to 3 times the width of the first signal line 46. The interval I′ is in proportion to the impedance of the high frequency circuit board 40. Further, when the interval I′ is greater, the impedance of the high frequency circuit board 40 becomes greater.

It should be noted that the high frequency circuit board 40 is configured to transmit a high frequency signal having a frequency higher than 100 MHz. The high frequency circuit board 40 may be a hard circuit board or a flexible circuit board.

FIG. 4 is a schematic view of another embodiment of a high frequency circuit board of the present invention. Referring to FIG. 4, the high frequency circuit board 50 comprises a first dielectric layer 52, a second dielectric layer 51, a first signal line 56a, a second signal line 56b, a first electromagnetic interference (EMI) shielding layer 53 and a second electromagnetic interference (EMI) shielding layer 54. The first signal line 56a and the second signal line 56b are formed on the first dielectric layer 52. The second dielectric 51 overlays an upper layer of the first dielectric layer 52 and covers the first signal line 56a and the second signal line 56b. The first EMI shielding layer 53 overlays the second dielectric layer 51 and has a gap 58 formed thereon and at a position corresponding to the positions of the first signal line 56a and the second signal line 56b. The first dielectric layer 52 and the second dielectric layer 51 are overlapped to each other. The first dielectric layer 52 is made of a dielectric material. The second EMI shielding layer 54 covers a lower surface of the first dielectric layer 52.

As shown in FIG. 4, the second dielectric layer 51 defines a first projection area R₁″ on which the first signal line 56a is vertically projected, and a second projection area R₂″ on which the second signal line 56b is vertically projected. The first EMI shielding layer 53 has a first side 581 and a second side 582 defining the gap 58 therebetween. The first projection area R₁″ and the second projection area R₂″ are positioned between the first side 581 and the second side 582 within the gap 58. An interval is disposed between the first projection area R₁″ and the first side 581 while an interval I₂″ is between the second projection area R₂″ and the second side 582. The interval I₁″ is equal to the interval I₂″. The interval I₁″ and the interval I₂″ are respectively 0.5 to 3 times the widths of the first signal line 56a and the second signal line 56b.

It should be noted that the high frequency circuit board 50 is configured to transmit a high frequency signal having a frequency higher than 100 MHz. The high frequency circuit board 50 may be a hard circuit board or a flexible circuit board.

According to the above embodiments, the high frequency circuit boards 30, 40 and 50 comprise the first EMI shielding layer 33, 43 and 53 which have the gaps 38, 48 and 58 being formed thereon and corresponding to the first and second signal lines 36, 46, 56a and 56b. Since the first EMI shielding layers 33, 43 and 53 are made of metal material, the gaps 38, 48 and 58 are added to increase the impedance of the high frequency circuit boards 30, 40 and 50. Accordingly, the impedance required by the high frequency circuit boards 30, 40 and 50 can be achieved, e.g. to a range between 50 and 100 ohm, without increasing the thickness of the dielectric layers 31, 32, 41, 42, 51 and 52.

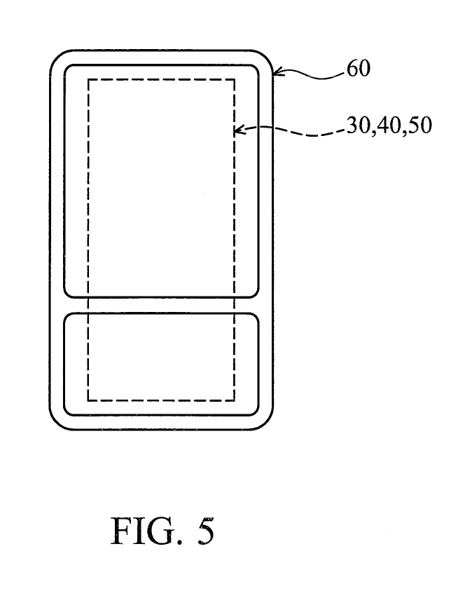

FIG. 5 is a schematic view of an electronic device according to one embodiment of the present invention. Referring to FIG. 5, an electronic device 60, for example a cell phone, comprises the high frequency circuit boards 30, 40 and 50. According to the above disclosed embodiments, the high frequency circuit boards 30, 40 and 50 can achieve required impedance without increasing thickness thereof. Therefore, the high frequency circuit boards 30, 40 and 50 does not hinder thinner and lighter weight trends of the electronic device 60.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A high frequency circuit board, comprising:
a first dielectric layer;
a first signal line formed on an upper surface of the first dielectric layer;
a second dielectric layer overlaying the upper surface of the first dielectric layer and covering the first signal line; and
a first electromagnetic interference (EMI) shielding layer overlaying the second dielectric layer and having a gap formed thereon, wherein the gap is formed at a position corresponding to the position of the first signal line.

2. The high frequency circuit board as claimed in claim 1, wherein the second dielectric layer defines a first projection area on which the first signal line is vertically projected, and the first projection area is positioned within the gap.

3. The high frequency circuit board as claimed in claim 2, wherein the first EMI shielding layer has a first side and a second side defining the gap therebetween, the first projection area is positioned between the first side and the second side, and an interval between the first projection area and the first side is 0.5 to 3 times the width of the first signal line.

4. The high frequency circuit board as claimed in claim 2, wherein the first projection area is positioned at the center of the gap.

5. The high frequency circuit board as claimed in claim 1, wherein the high frequency circuit board is configured to transmit a high frequency signal having a frequency higher than 100 MHz.

6. The high frequency circuit board as claimed in claim 1, wherein the high frequency circuit board is a hard circuit board or a flexible circuit board.

7. The high frequency circuit board as claimed in claim 3, further comprising: a second signal line formed on the first dielectric layer, wherein the second dielectric layer defines a second projection area on which the second signal line is vertically projected, and the second projection area is positioned between the first side and the second side within the gap.

8. The high frequency circuit board as claimed in claim 7, wherein an interval between the second projection area and the second side is 0.5 to 3 times the width of the second signal line.

9. The high frequency circuit board as claimed in claim 1, further comprising a second EMI shielding layer covering a lower surface of the first dielectric layer.

10. The high frequency circuit board as claimed in claim 9, wherein the first EMI shielding layer and the second EMI shielding layer are made of metal material.

11. An electronic device, comprising:
a high frequency circuit board, comprising:
a first dielectric layer;
a first signal line formed on an upper surface of the first dielectric layer;
a second dielectric layer overlaying the upper surface of the first dielectric layer and covering the first signal line; and
a first electromagnetic interference (EMI) shielding layer overlaying the second dielectric layer and having a gap formed thereon, wherein the gap is formed at a position corresponding to the position of the first signal line.

12. The electronic device as claimed in claim 11, wherein the second dielectric layer defines a first projection area on which the first signal line is vertically projected, and the first projection area is positioned within the gap.

13. The electronic device as claimed in claim 12, wherein the first EMI shielding layer has a first side and a second side defining the gap therebetween, the first projection area is positioned between the first side and the second side, and an interval between the first projection area and the first side is 0.5 to 3 times the width of the first signal line.

14. The electronic device as claimed in claim 12, wherein the first projection area is positioned at the center of the gap.

15. The electronic device as claimed in claim 11, wherein the high frequency circuit board is configured to transmit a high frequency signal having a frequency higher than 100 MHz.

16. The electronic device as claimed in claim 11, wherein the high frequency circuit board is a hard circuit board or a flexible circuit board.

17. The electronic device as claimed in claim 13, wherein the high frequency circuit board further comprises a second signal line formed on the first dielectric layer, the second dielectric layer defines a second projection area on which the second signal line is vertically projected, and the second projection area is positioned between the first side and the second side within the gap.

18. The electronic device as claimed in claim 17, wherein an interval between the second projection area and the second side is 0.5 to 3 times the width of the second signal line.

19. The electronic device as claimed in claim 11, wherein the high frequency circuit board further comprises a second EMI shielding layer covering a lower surface of the first dielectric layer.

20. The electronic device as claimed in claim 19, wherein the first EMI shielding layer and the second EMI shielding layer are made of metal material.
